(19) United States
(12) Patent Application Publication
(10) Pub. No.: US 2006/0034409 A1
(43) Pub. Date: Feb. 16, 2006

(54) Digital vco and pll circuit using the digital vco

(76) Inventors: Takashi Aoyama, Tokyo (JP); Hiroshi Miyagi, Yokohama (JP)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/523,209

(22) PCT Filed: Jul. 25, 2003
(86) PCT No.: PCT/JP03/09454

§ 371 Date: Jul. 19, 2005

(30) Foreign Application Priority Data
Aug. 2, 2002 (JP) 2002-226139

(51) Int. Cl. H03D 3/24

(52) U.S. Cl. 375/376

(57) ABSTRACT

A digital VCO includes an A/D converter (11) for converting a given analog signal to a digital signal, a quartz oscillation circuit (12) having a quartz oscillator for generating a signal having a predetermined frequency, and a variable divider circuit (13) for varying the division ratio according to the digital signal and divides the frequency of the signal generated by the quartz oscillation circuit (12) according to the division ratio.

### TECHNICAL FIELD

The present invention relates to a digital voltage controlled oscillator (hereinafter called “VCO”) and a phase locked loop (hereinafter called “PLL”) circuit using the digital VCO.

### BACKGROUND ART

FIG. 1A shows an example of conventional VCO.

As shown in FIG. 1A, a conventional VCO 40 comprises two constant current sources 41, two switches 42, a capacitor 43, a comparator 44 and a variable base voltage circuit 45 for example.

In the VCO 40, the current through the constant current sources 41 is varied based on a regulated voltage, Vin, the on-off operations of the switches 42 are controlled based on output signals from the comparator 44. By thus controlling both the current through the constant current sources 41 and the operation of the switches 42 based on the regulated voltage, Vin, and the output oscillation signals (hereinafter called “oscillation signal”) of the comparator 44, consequently a charged or discharged current from the capacitor 43 is varied, the on-off operations of the comparator 44 are controlled and frequencies of the oscillation signal coming out of the comparator 44 are varied. Meanwhile, the base voltage output from the variable base voltage circuit 45 is varied based on a high or low level of the oscillation signals coming out of the comparator 44 and is inputted into a terminal of the comparator 44.

Meanwhile, a VCO 46 shown in FIG. 1B is also an example of a conventional VCO.

The VCO 46 shown in FIG. 1B, being called a ring oscillator, generates an oscillation signal having a predefined frequency by feeding an oscillation signal coming out of an inverter 47 back to the input into another inverter 47. A frequency of the oscillation signal can be variably set to a predefined frequency corresponding to the number of the inverters 47 serially connected in the circuit or the bias current inputted into the inverters 47, and for instance, an increased bias current provided by the constant current sources 48 will shorten a signal switching operation time of the inverters 47 and thereby increase the oscillation signal frequency.

As such, the conventional VCO 40 or 46 has variably set the oscillation signal frequency based on the regulated Vin (an analogue value) inputted thereto.

However, the oscillation signal frequency coming out of the conventional VCO 40 or 46 depends largely on characteristics of elements such as not-shown transistor, capacitor 43, or not-shown resistor, et cetera, which constitute the VCO 40 or 46 and variation of each element in the respective characteristics has collectively caused a large variation in the free-run frequency of the VCO 40 or 46.

And if the variation in the free-run frequency becomes wider than a capture range, a failure in phase-locking the input signal is caused, resulting in a problem of failing to function as a PLL circuit, when applying the above described VCO 40 or 46 to a PLL circuit.

Consequently, the VCO 40 has conventionally been equipped with a variation control circuit for suppressing such variation of the free-run frequency,

FIG. 1C illustrates a circuitry of a VCO 49 which is, as an example, the VCO 40 shown in FIG. 1A equipped with a variation adjustment circuit 50.

The variation adjustment circuit 50 shown in FIG. 1C provides the constant current sources 41 with a variation suppression voltage Vinb so as to make an oscillation signal frequency coming out of the comparator 44 a required frequency, thereby suppressing a free-run frequency variation caused by the characteristics of the elements constituting the VCO 49. That is, a conventional VCO 49 compensates variations of elements characteristics by monitoring the oscillation signal frequency and controlling the above described frequency based thereupon before shipping out the product.

However, even by the variation adjustment circuit 50 disposed for suppressing a free-run frequency as shown in FIG. 1C, a fluctuation of the free-run frequency has sometimes occurred after the product shipment due to the temperature characteristics of elements in a place where, for instance, the ambient temperatures are different from the temperature under which a compensation for the element variations underwent. That is, even with a successful compensation prior to the product shipment by the variation adjustment circuit 50 equipped in the VCO 40 shown in FIG. 1A and disposed for suppressing the free-run frequency variation due to the manufacturing variation of each element, a free-run frequency fluctuation due to the temperature characteristics of each element has hardly been suppressed.

It has also been difficult to compensate for a free-run frequency variation due to a fluctuation of the supply voltage by using the variation adjustment circuit 50 described above. That is, for instance, even with a successful adjustment of a free-run frequency to a required frequency by using the variation adjustment circuit 50 prior to the product shipment, for instance, there still has been a problem that the required free-run frequency cannot be obtained when the supply voltage for the above described VCO 49 is varied by the user operation after the product shipment.

Thus the conventional VCO 49, even with a successful suppression of free-run frequency due to the manufacturing variations of the elements, has been unable to suppress a variation of free-run frequency due to fluctuations in the temperature characteristics or the supply voltage, and therefore the free-run frequency has not been able to stay within the capture range, resulting in a failure to phase-lock the input signal when applying to a PLL circuit.

Consequently, the purpose of the present invention is to provide a digital VCO capable of setting an oscillation signal frequency at a required frequency unaffected by the manufacturing variations or the temperature characteristics of the used elements, and a fluctuation of the supply voltage.

Another purpose is to provide a PLL circuit having a satisfactory performance unaffected by the manufacturing variations or temperature characteristics of the used elements, and a fluctuation of the supply voltage.

### DISCLOSURE OF INVENTION

In order to solve the problems as described above, the present invention comprises as follows.

That is, a digital VCO according to the present invention comprises a quartz oscillation circuit generating a signal having a predefined frequency by using a quartz oscillator, a conversion circuit converting a given analog signal to a digital signal, and a divider circuit dividing a frequency of signal generating in the quartz oscillation circuit by a division ratio according to the digital signal.

Thus, since a quartz oscillator having a small frequency variation is used, that is unaffected by the manufacturing variations or temperature characteristics of the elements and a fluctuation of the supply source voltage, and a digital VCO is contrived to be capable of generating a signal having a required frequency by using a signal generated based on such quartz oscillator, it is possible to reduce a frequency variation of the output signal due to the manufacturing variations or temperature characteristics of the elements, and a voltage fluctuation of the supply source.

Meanwhile, the digital VCO may comprise a sample holding circuit for taking in a digital signal outputted from the conversion circuit in a predefined interval.

And it is preferable to comprise so that the sample holding circuit whose sampling time is longer interval than that used by the conversion circuit holds and outputs a digital signal taken in from the conversion circuit within a holding time.

This contrivance enables the digital signals to be inputted into the divider circuit in a constant sampling interval even if the sampling times in the conversion circuit are changed, and thereby a malfunction of the divider circuit will be prevented.

Meanwhile, the digital VCO may comprise a compensation circuit compensating for an offset error of the digital signal occurring in the conversion circuit.

The offset error indicates, for example, a differential error between an erroneous digital data caused by the manufacturing variations of the conversion circuit and the correct digital data unaffected by such manufacturing variations, and in such a case in which an output signal value is not indicating as required (i.e., an error exists), offsetting such digital signal so as to become as required will compensate for an offset error caused by the manufacturing variations of the conversion circuit.

Meanwhile, the digital VCO may comprise a limit circuit limiting a variation range of the division ratio.

This limits a variation range in an oscillation frequency outputting form the digital VCO.

Meanwhile, the PLL circuit according to the present invention adjusting a phase difference between an input signal and a base signal in the PLL circuit comprises a detection circuit detecting a phase difference between the input signal and a base signal, a conversion circuit converting a signal indicating the phase difference to a digital signal, a quartz oscillation circuit generating a signal having a predefined frequency by using a quartz oscillator, and a divider circuit dividing a frequency of signal generated by the quartz oscillation circuit by a division ratio according to the digital signal, wherein a phase difference between the input signal and the base signal is adjusted according to a divided frequency signal by the divider circuit.

As such, since a PLL circuit is applied by the digital VCO using a quartz oscillator having a small frequency variation and capable of generating a signal having a required frequency by using a signal generated based on such a quartz oscillator, it is possible to reduce a frequency variation of the free-run frequency of the digital VCO and prevent an occurrence of a state in which the free-run frequency goes out of a capture range and an input signal fails to be phase-locked.

Meanwhile, the PLL circuit may comprise a sample holding circuit taking in, in a predefined interval, digital data outputted from the conversion circuit.

This enables the digital signals to be inputted into the divider circuit in a constant sampling interval even if the sampling times in the conversion circuit are changed, and thereby a malfunction of the divider circuit will be prevented.

### BRIEF DESCRIPTION OF THE DRAWINGS

The present invention will be more apparent from the following descriptions when the accompanying drawings are referenced.

FIG. 1A illustrates a conventional VCO;

FIG. 1B illustrates a conventional VCO;

FIG. 1C illustrates a circuitry of a conventional VCO equipped with a variation adjustment circuit;

FIG. 2 illustrates a theoretical architecture of a digital VCO according to an embodiment of the present invention;

FIG. 3 illustrates a circuitry of PLL circuit equipped with a digital VCO according to an embodiment of the present invention; and

FIG. 4 shows a detailed description of a digital VCO according to an embodiment of the present invention.

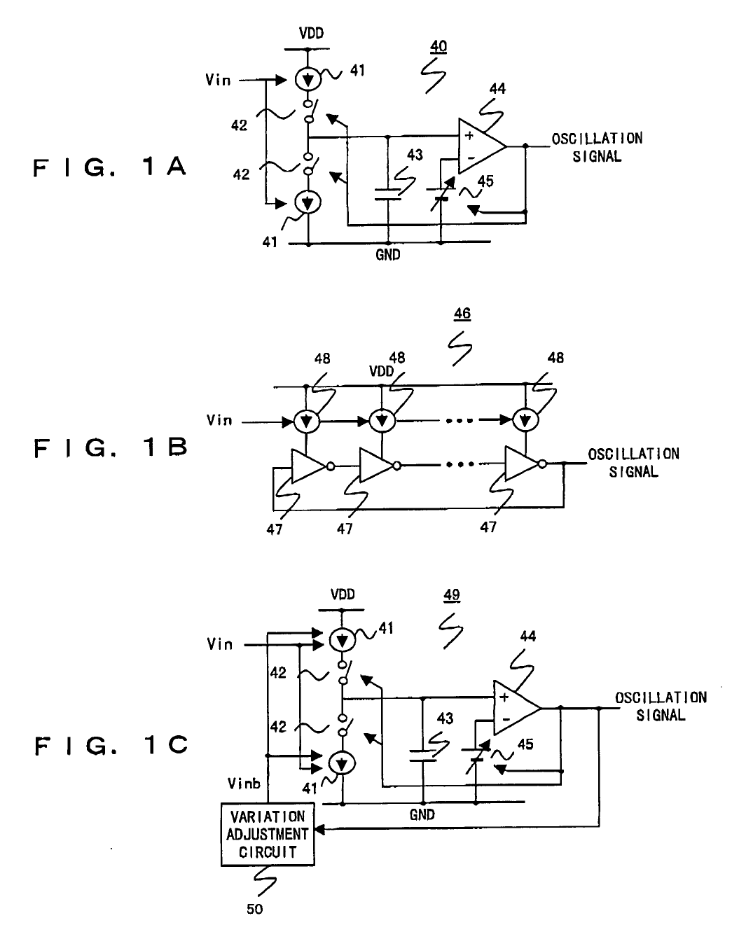

### BEST MOOD FOR CARRYING OUT THE INVENTION

The preferred embodiment of the present invention is described in reference to the accompanying drawings as follows.

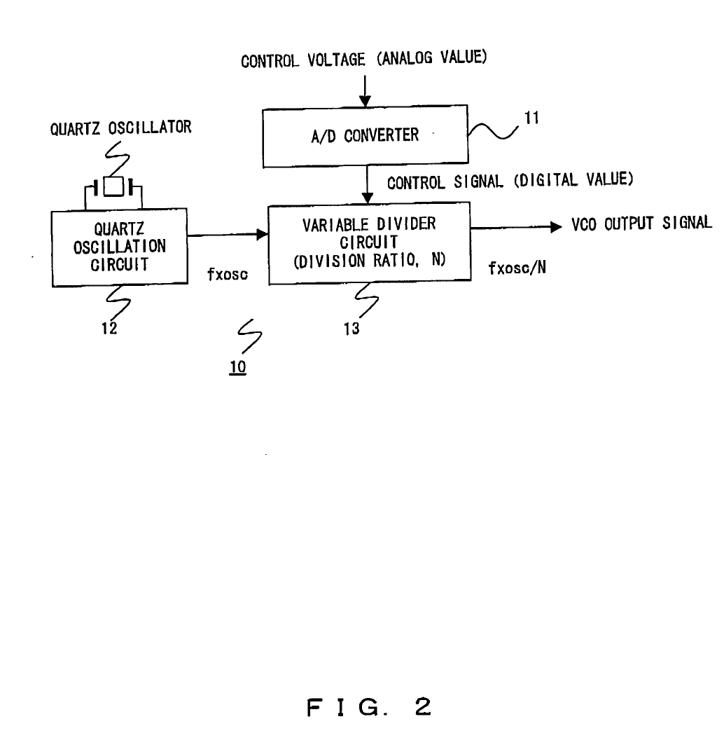

FIG. 2 illustrates a theoretical architecture of a digital VCO according to the embodiment of the present invention.

In FIG. 2, the digital VCO 10 comprises an A/D converter 11 (noted as conversion circuit in claims herein) converting a given analog signal to a digital signal, a quartz oscillation circuit 12 (noted as quartz oscillation circuit in claims herein) generating a signal having a predefined frequency by a quartz oscillator equipped therein, and a variable divider circuit 13 (noted as divider circuit in claims herein) varying division ratios according to the above described digital signal and dividing the frequency of a signal generated by the quartz oscillation circuit 12 according to the division ratio. For example, if the frequency of an oscillation signal generated by the quartz oscillation circuit 12 is defined as fxosc, the variable divider circuit 13 varies the division ratio to N (where N is an integer, 1 or greater) based on the inputted digital signal, and outputs an oscillation signal at the frequency of an fxosc divided by N.

The above described quartz oscillation circuit 12, because of the characteristics of a quartz oscillator, is capable of generating signals with small frequency variation due to the manufacturing variations, temperature characteristics, and a fluctuation of the supply voltage.

As such, by using a quartz oscillator having small frequency variation and by comprising a digital VCO capable of generating an oscillation signal having a predefined frequency from a signal generated based on the quartz oscillator, it is possible to reduce a variation of free-run frequency due to the manufacturing variations, temperature characteristics, and a fluctuation of the supply voltage. Note that the above described variable divider circuit 13 is, for example, a well known programmable divider for dividing a frequency of an input signal based on a digital signal, and a drawing or description of detailed circuitry thereof is hence omitted herein. Likewise, an A/D converter 11 can also be implemented by a well known circuitry, and a drawing or description of detailed circuitry thereof is hence omitted herein.

A circuitry of a PLL circuit equipped with the above described digital VCO 10 is then described as an example.

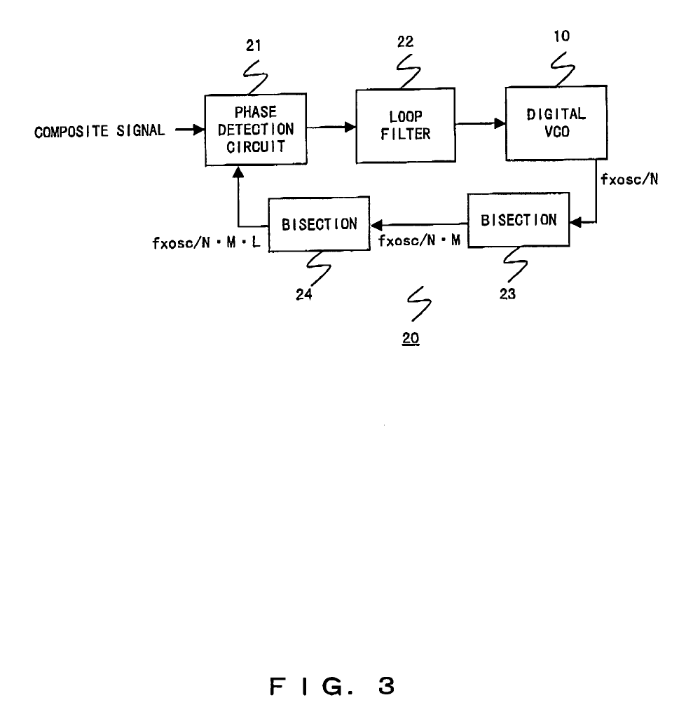

FIG. 3 illustrates a circuitry of PLL circuit equipped with the digital VCO 10. Note that while the PLL circuit shown in FIG. 3 is the one for an FM receiver, the digital VCO 10 is applicable not only to an FM receiver but also to various PLL circuits such as AM receiver and audio apparatuses, et cetera.

The PLL circuit 20 shown in FIG. 3 comprises a phase detection circuit 21 (noted as detection circuit in claims herein) generating a signal (which is a voltage value indicating a phase difference; hereinafter called “analog signal”) based on the phase difference between a phase of the composite signal received by an FM receiver and that of the base signal, a loop filter 22 required for stabilizing the control loop of the PLL circuit 20, a digital VCO 10, a first divider circuit 23 bisecting a base signal frequency (76 kHz for instance) outputted from the digital VCO 10, and a second divider circuit 24 bisecting the bisected base signal frequency (38 kHz for instance) by the first divider circuit 23.

The PLL circuit 20 shown in FIG. 31 which is the circuit for generating a base oscillation signal (38 kHz) in synchronous with a pilot signal (19 kHz) included in the composite signal, generates a base oscillation signal, in the digital VCO equipped therein, having a required frequency based on the phase difference between the bisected base oscillation signal (19 kHz) and the pilot signal. Then a required voice signal is gained by mixing the base oscillation signal outputted from the PLL circuit 20 with the composite signal by using a not-shown mixer.

As such, the free-run frequency coming out of the digital VCO 10 is stable without fluctuation when the digital VCO 10 is applied in the PLL circuit 20 so as to be able to prevent a failure of the input signal being unlocked due to the free-run frequency going out of the capture range.

The abovementioned digital VCO 10 is then described in more details as follows.

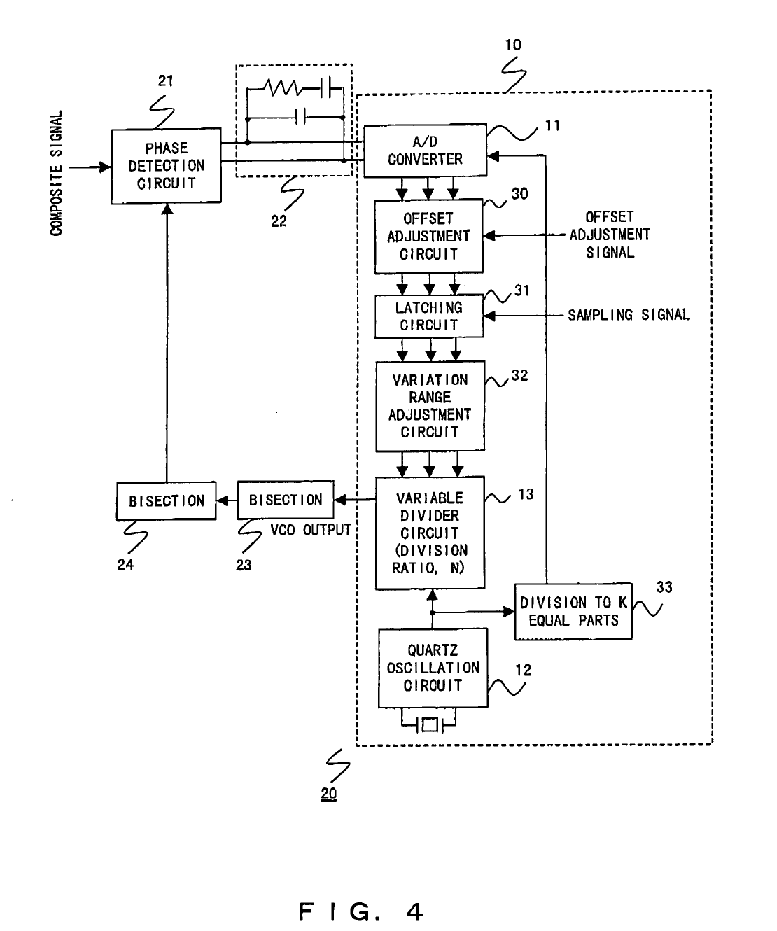

FIG. 4 shows a detailed description of the digital VCO 10 mentioned above.

As shown in FIG. 4, the digital VCO 10 is equipped with an offset adjustment circuit 30 (noted as compensation circuit in claims herein), a latching circuit 31 (noted as sample holding circuit in claims herein) and a variation range adjustment circuit 32 (noted as limit circuit in claims herein) between the A/D converter 11 and the variable divider circuit 13. Additionally, the third divider circuit 33 divides an oscillation signal frequency outputted from the quartz oscillation circuit 12 into K equal parts (where K is an integer, 1 or greater), and the divided signal is inputted into the A/D converter 11 as the clock signal for operating the A/D conversion. Note that each of the offset adjustment circuit 30, the latching circuit 31 and the variation range adjustment circuit 32 can be configured by a well known circuitry, and hence a drawing or description of detailed circuitry thereof is omitted herein.

The above described offset adjustment circuit 30 is the circuit for compensating for an offset error of the digital signal in the A/D converter 11 due to a manufacturing variation or temperature characteristics based on an adjustment signal preset externally. Incidentally, what the above described “compensating for an offset error” means is that, for instance, if a digital signal data outputted from the A/D converter 11 is changed to a “001010” from the correct “001011” due to a manufacturing variation or temperature characteristics of the A/D converter 11, the digital signal data will be compensated (or offset) to the correct “001011” by an adjustment signal inputted from an external control circuit such as a microcomputer or by an offset adjustment signal once taken in by an internal memory.

As such, it is possible to compensate for an offset error of a digital signal from the A/D converter 11 due to a manufacturing variation or temperature characteristics and prevent a malfunction of the digital VCO 10 by equipping the offset adjustment circuit 30 in the digital VCO 10.

Meanwhile, the above described latching circuit 31 is a circuit for sampling, in a predefined interval, the data inputted from the offset adjustment circuit 30, and outputting the data in the predefined interval. In other words, it is a circuit for outputting digital signals in a wider sampling interval than that of the A/D converter 11.

This contrivance will enable the digital signals to be inputted into the variable divider circuit 13 in a constant sampling interval even if the sampling times in the A/D converter 11 are changed, and thereby a malfunction of the variable divider circuit 13 will be prevented.

Meanwhile, the above described variation range adjustment circuit 32 is the circuit for limiting a range variation of division ratio in the variable divider circuit 13.

That is, the variation range adjustment circuit 32 outputs the signal value fixed to the lowest limit if an input digital signal value is lower than a predefined limit: while the circuit 32 outputs the signal value fixed to the highest limit if an input digital signal value is higher than a predefined limit.

By the variation range adjustment circuit 32 thus limiting a variation range of the oscillation frequency outputting from the digital VCO 10, it is possible to avoid a digital signal indicating a large phase difference from being inputted into the variable divider circuit 13 and prevent a malfunction of the PLL circuit 20.

Meanwhile, the offset adjustment circuit 30 in the present embodiment is disposed for compensating an offset error in a digital signal outputted from the A/D converter 11 based on an external adjustment signal prior to the product shipment as described above, but it is possible to compare between a digital signal outputted from the offset adjustment circuit 30 and a predefined base signal and accordingly adjust the offset error of a digital signal based on the comparison result.

According to the present invention, since a quartz oscillator having a small frequency variation is used and a digital VCO is contrived to be capable of generating a signal having a predefined frequency by using a signal generated based on such a quartz oscillator, it is possible to reduce a frequency variation of the output signal due to the manufacturing variations or temperature characteristics of the elements, and a voltage fluctuation of the supply source.

Also, by applying the digital VCO to a PLL circuit, it is possible to prevent an occurrence of state in which an input signal fails to be phase-locked as a result of the free-run frequency going out of the capture range, because an application of the digital VCO to a PLL circuit minimizes a variation of the free-run frequency.

1. A digital VCO, comprising:
a quartz oscillation circuit generating a signal having a predefined frequency by using a quartz oscillator;
a conversion circuit converting a given analog signal to a digital signal; and
a divider circuit dividing a frequency of signal generated in said quartz oscillation circuit by a division ratio according to said digital signal.

2. The digital VCO in claim 1, further comprising
a sample holding circuit taking in a digital signal outputted from said conversion circuit in a predefined interval.

3. The digital VCO in claim 2, wherein
said sample holding circuit, whose sampling time is longer interval than that used by said conversion circuit, holds and outputs a digital signal taken in from said conversion circuit within a holding time.

4. The digital VCO in claim 1, further comprising
a compensation circuit compensating for an offset error of said digital signal occurring in said conversion circuit.

5. The digital VCO in claim 1, further comprising
a limit circuit limiting a variation range of said division ratio.

6. A PLL circuit adjusting a phase difference between an input signal and a base signal, including:
a detection circuit detecting a phase difference between said input signal and a base signal;
conversion means for converting a signal indicating said phase difference to a digital signal;
a quartz oscillation circuit generating a signal having a predefined frequency by using a quartz oscillator; and
a divider circuit dividing a frequency of signal generated by said quartz oscillation circuit by a division ratio according to said digital signal, wherein
a phase difference between said input signal and said base signal is adjusted according to a divided frequency signal by said divider circuit.

7. The PLL circuit in claim 6, further comprising
a sample holding circuit taking in, in a predefined interval, digital data outputted from said conversion circuit.
